(19) United States
(12) Patent Application Publication
(10) Pub. No.: US 2025/0071909 A1
(43) Pub. Date: Feb. 27, 2025

(54) METHOD OF MANUFACTURING CIRCUIT BOARD

(71) Applicant: HAESUNG DS CO., LTD., Gyeongsangnam-do (KR)

(72) Inventor: Soon-Chul KWON, Gyeongsangnam-do (KR)

(21) Appl. No.: 18/813,219

(22) Filed: Aug. 23, 2024

(30) Foreign Application Priority Data
Aug. 25, 2023 (KR) 10-2023-0111979

(51) Int. Cl. H05K 3/06; H05K 3/00; H05K 3/02; H05K 3/34; H05K 3/40; H05K 3/46

(52) U.S. Cl. CPC H05K 3/064; H05K 3/002; H05K 3/025; H05K 3/3452; H05K 3/4038; H05K 3/4652

(57) ABSTRACT

Provided is a method of manufacturing a circuit board including: preparing a first stack in which a first foil and a second foil are stacked, wherein a thickness of the second foil is greater than a thickness of the first foil, forming a first circuit pattern by etching the first foil, forming a second stack by arranging an insulating layer covering the first circuit pattern and a third foil attached to the insulating layer, reducing the thickness of the second foil and a thickness of the third foil through a half-etching process, removing the second foil of which the thickness has been reduced, and forming a second circuit pattern by etching the third foil.

### CROSS-REFERENCE TO RELATED APPLICATION

This application is based on and claims priority under 35 U.S.C. § 119 to Korean Patent Application No. 10-2023-0111979, filed on Aug. 25, 2023, in the Korean Intellectual Property Office, the disclosure of which is incorporated by reference herein in its entirety.

### BACKGROUND

### 1. Field

The disclosure relates to a method of manufacturing a circuit board.

### 2. Description of the Related Art

Usually, a circuit board may be configured by forming a wiring pattern from a conductive material, e.g., copper, on an electrically insulated material. Recently, formation of microcircuits is required due to high integration of semiconductor chips.

To implement such specifications of microcircuits and small thicknesses of circuit boards, a circuit board having a buried pattern, which is to bury a portion of a circuit pattern by using an insulating material of the circuit board, has been developed.

Among methods of forming microcircuits applied to manufacturing processes of circuit boards having buried patterns, a modified semi-additive process (MSAP) is widely known. MSAP is a method in which plating is necessarily performed to form a circuit pattern, and requires a plurality of processes related to plating for manufacturing the circuit board.

Korean Patent Publication No. 10-2016-0107435 discloses a process of manufacturing a circuit board using the MSAP method.

### SUMMARY

Provided is a method of manufacturing a circuit board.

Additional aspects will be set forth in part in the description which follows and, in part, will be apparent from the description, or may be learned by practice of the presented embodiments of the disclosure.

According to an aspect of the disclosure, a method of manufacturing a circuit board includes preparing a first stack in which a first foil and a second foil are stacked, wherein a thickness of the second foil is greater than a thickness of the first foil, forming a first circuit pattern by etching the first foil, forming a second stack by arranging an insulating layer covering the first circuit pattern and a third foil attached to the insulating layer, reducing the thickness of the second foil and a thickness of the third foil through a half-etching process, removing the second foil of which the thickness has been reduced, and forming a second circuit pattern by etching the third foil.

The thickness of the first foil of the first stack may be from about 2 μm to about 3 μm.

The thickness of the second foil of the first stack may be from about 12 μm to about 18 μm. The first stack may include a carrier attached to the second foil.

The thickness of the third foil of the second stack may be from about 12 μm to about 18 μm.

The method may further include, before the removing of the second foil of which the thickness has been reduced, forming a via hole electrically connecting the first circuit pattern to the third foil.

After the removing of the second foil of which the thickness has been reduced, when an etching resist pattern is formed in the third foil to form the second circuit pattern by etching, an etching resist layer may be formed on a surface, from which the second foil has been removed, to protect the first circuit pattern during etching.

The method may further include, after the forming of the second circuit pattern, arranging a solder resist layer covering a portion of the first circuit pattern and a portion of the second circuit pattern.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a circuit board according to an embodiment;

FIGS. 2 to 11 are diagrams illustrating a process of manufacturing a circuit board, according to an embodiment; and

FIG. 12 is a flowchart schematically illustrating operations of a method of manufacturing a circuit board, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings. In addition, in the present specification and the drawings, same reference numerals will be used for components having substantially same configurations to omit repeated descriptions, and in the drawings, for convenience of understanding, sizes, a ratio between lengths, and the like may be exaggerated.

The disclosure will be clearly understood with reference to embodiments described in detail in conjunction with the accompanying drawings. However, the disclosure is not limited to embodiments disclosed herein and will be implemented in various forms. The disclosure is provided for those skilled in the art to fully understand the category of the disclosure, and is only defined by the scope of the claims.

Terms used herein is only to describe embodiments and are not to limit the disclosure. In the present specification, unless particularly mentioned in the context, singular forms also include plural forms. When used in the specification, “comprises” and/or “comprising” does not indicate existence or addition of one or more other components, processes, operations, and/or elements other than components, processes, operations, and/or elements those have been mentioned. Terms such as “first”, “second”, and the like may be used to describe various components, but the components are not limited to the terms. The terms are used only to distinguish one component from other components.

The term ‘half-etching’ used herein does not only indicate a case in which a precise half of an etching target is etched, and is used in a broader sense to indicate other cases except a case in which the etching target is completely etched. That is, the term ‘half-etching’ indicates a case where the etching target is partially etched, including a case in which most of the etching target is etched.

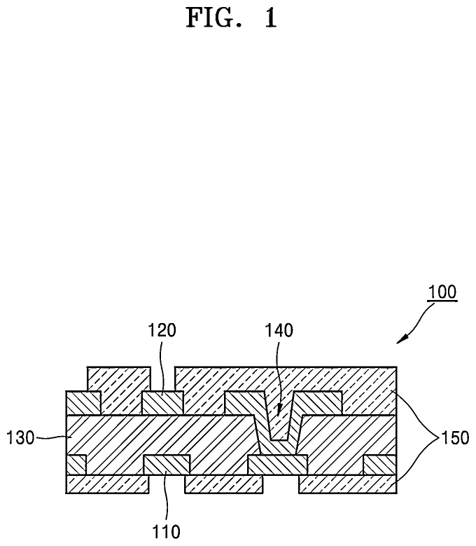

FIG. 1 is a cross-sectional view of a circuit board 100 according to an embodiment. The circuit board 100 manufactured according to the embodiment may have characteristics of a flexible circuit board or a rigid circuit board.

As illustrated in FIG. 1, the circuit board 100 according to an embodiment may include a first circuit pattern 110, a second circuit pattern 120, an insulating layer 130, a via hole 140, and a solder resist layer 150.

The first circuit pattern 110 and the second circuit pattern 120 include copper.

The first circuit pattern 110 and the second circuit pattern 120, according to the embodiment, include copper, but the disclosure is not limited thereto. That is, any electrically conductive material may be limitlessly used for forming the first circuit pattern 110 and the second circuit pattern 120 according to the disclosure. For example, the first circuit pattern 110 and the second circuit pattern 120 may include various materials such as silver (Ag) and gold (Au).

The insulating layer 130 may include a pre-impregnated (PrePreg) material.

The insulating layer 130 according to the embodiment may include a PrePreg material, but the disclosure is not limited thereto. Any electrically insulated material may be limitlessly used as the material of the insulating layer 130. For example, the insulating layer 130 according to the disclosure may include a resin material that is electrically insulated, for example, various materials such as epoxy, polyimide (PI), polyethylene terephthalate (PET), and polycarbonate (PC).

The via hole 140 may electrically connect the first circuit pattern 110 to the second circuit pattern 120, and may have a well-known via hole structure.

The solder resist layer 150 may partially cover the first circuit pattern 110 and the second circuit pattern 120 for protection, and a well-known solder resist may be used for the solder resist layer 150.

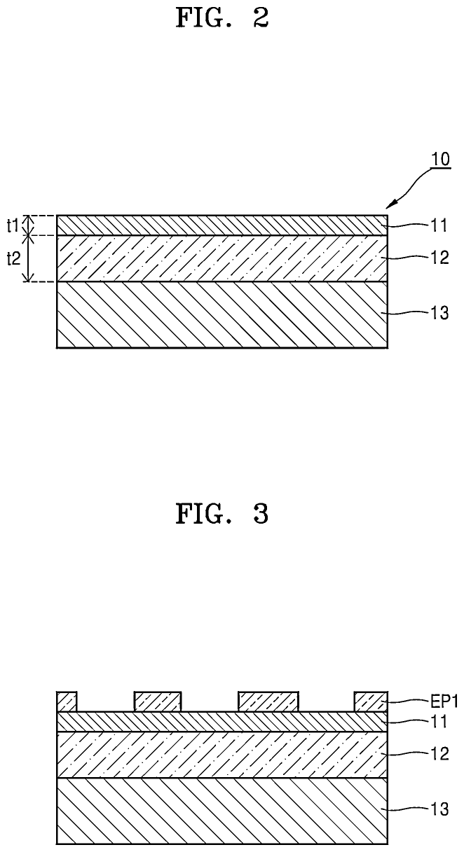

Hereinafter, a method of manufacturing the circuit board 100, according to the embodiment, will be described with reference to FIGS. 2 to 11.

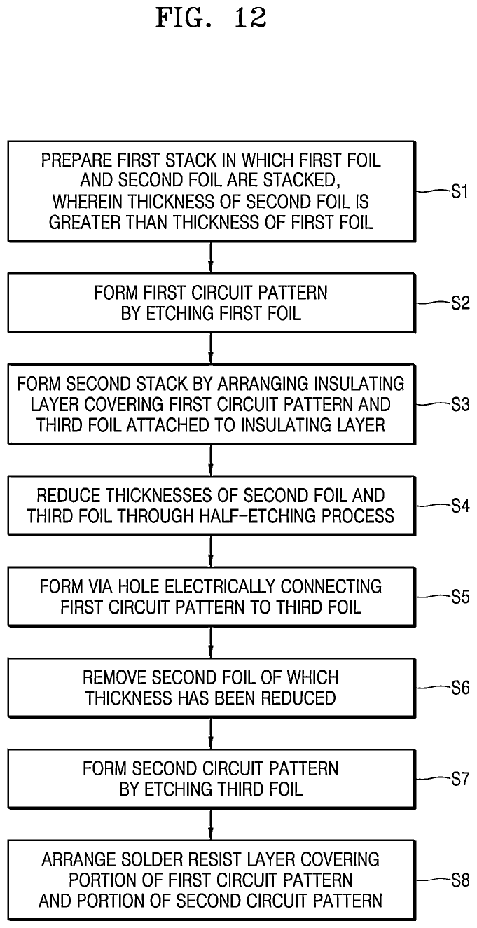

FIGS. 2 to 11 are diagrams illustrating a process of manufacturing the circuit board 100, according to an embodiment, and FIG. 12 is a flowchart schematically illustrating operations of the method of manufacturing the circuit board 100, according to an embodiment.

First, as illustrated in FIG. 2, a first stack 10, in which a first foil 11, a second foil 12, and a carrier 13 are stacked, is prepared by a manufacturer (S1).

The first foil 11 and the second foil 12 each include a copper foil, and are in close contact with each other.

According to the embodiment, the first foil 11 and the second foil 12 each include a copper foil, but the disclosure is not limited thereto. According to the disclosure, any electrically conductive material may be limitlessly applied to the first foil 11 and the second foil 12. For example, the first foil 11 and the second foil 12 may include various materials such as silver (Ag) and gold (Au).

According to the embodiment, the first foil 11 and the second foil 12 are in close contact with each other and there is no additional layer or material between the first foil 11 and the second foil 12, but the disclosure is not limited thereto. According to the disclosure, an adhesive layer or a peeling layer having a small thickness may be disposed between the first foil 11 and the second foil 12. When the peeling layer is disposed between the first foil 11 and the second foil 12, it is favorable for separating the first foil 11 and the second foil 12 from each other in the following processes.

It is desirable when a peel strength between the first foil 11 and the second foil 12 is 0.2 kgf/cm² or less, and such a peel strength facilitates peeling between the first foil 11 and the second foil 12 in the following processes.

A thickness t2 of the second foil 12 may be greater than a thickness t1 of the first foil 11.

A detailed thickness of each of the first foil 11 and the second foil 12 may be variously formed according to a shape, a width, a thickness, and a processing method of a microcircuit to be formed. However, in consideration of a general structure of microcircuits, the following example may be applied to the detailed thickness of each of the first foil 11 and the second foil 12.

That is, a thickness of the first foil 11 may be from about 2 μm to about 3 μm, and a thickness of the second foil 12 may be from about 12 μm to about 18 μm.

The carrier 13 may be attached to the second foil 12, and may support the first foil 11 and the second foil 12 in the manufacturing process.

That is, the carrier 13 may support the first foil 11 and the second foil 12 in the following processes including forming the first circuit pattern 110, applying pressure to form the insulating layer 130, and transferring.

A material of the carrier 13 may be determined in consideration of mechanical strength, surface smoothness, and the like, and various materials may be applied to the carrier 13. A PET film and a PI film may be applied as examples of the material of the carrier 13.

In the embodiment, the first stack 10 includes the carrier 13, but the disclosure is not limited thereto. That is, the first stack 10 according to the disclosure may not include the carrier 13.

Next, as illustrated in FIGS. 3 and 4, the first circuit pattern 110 is formed by etching the first foil 11 (S2).

In detail, a dry film photoresist (DFR) is disposed on a top surface of the first foil 11, and a first etching resist pattern EP1 is formed by using a photolithography process such as mask exposure, development, and the like (see FIG. 3). Next, the first circuit pattern 110 is formed by etching the first foil 11 by using the first etching resist pattern EP1 that has been formed (see FIG. 4).

A sulfuric acid hydrogen peroxide-based etchant may be used as an example of an etchant used in a process of etching the first foil 11.

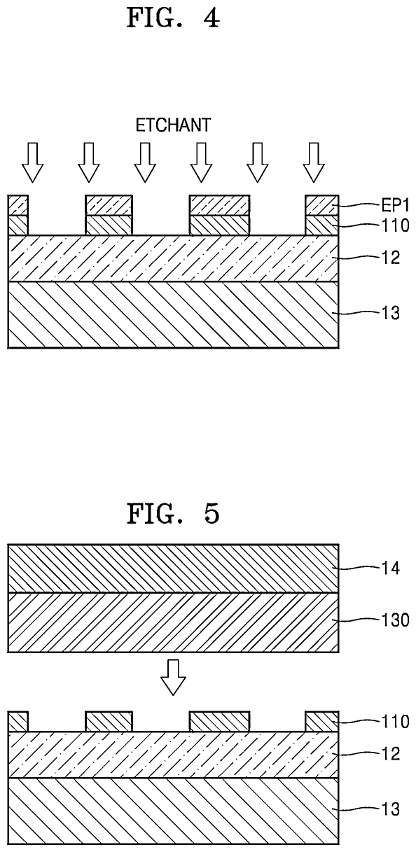

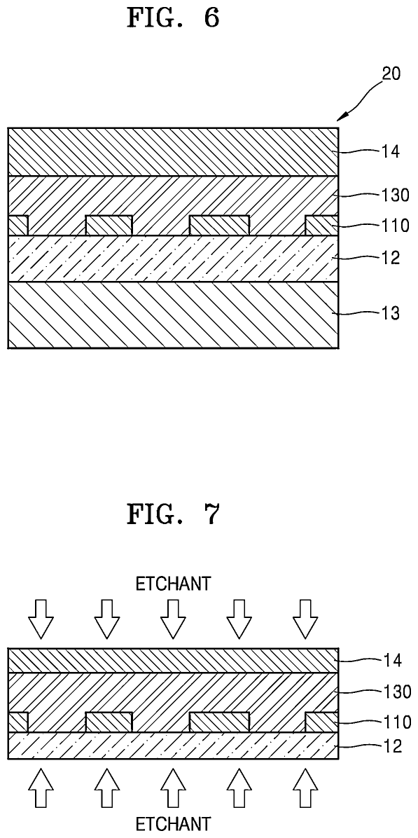

Next, as illustrated in FIGS. 5 and 6, the second stack 20 is formed by arranging the insulating layer 130 and a third foil 14 covering the first circuit pattern 110 (S3).

To do so, first, the first etching resist pattern EP1 is removed, and a material obtained by attaching the insulating layer 130 including a PrePreg material to the third foil 14, i.e., the copper foil, is prepared (see FIG. 5). Next, after placing the insulating layer 130 to cover the first circuit pattern 110, the second stack 20 illustrated in FIG. 6 is formed by heating and pressing.

Here, a detailed thickness of the third foil 14 may be variously formed according to a shape, a width, and a processing method of a microcircuit to be formed. However, in consideration of a general structure of microcircuits, a thickness of the third foil 14 may be from about 12 μm to about 18 μm. In addition, processes of heating and pressing to form the second stack 20 may be formed by using a hot press machine, a hot press roller, a double belt press, and the like known in public.

According to the embodiment, a material, in which the insulating layer 130 including PrePreg is previously attached to the third foil 14, is prepared, and the material is arranged to cover the first circuit pattern 110, but the disclosure is not limited thereto. That is, according to the disclosure, the third foil 14 and the insulating layer 130 may be separately prepared, and may be attached to each other right before pressing.

Next, as illustrated in FIG. 7, thicknesses of the second foil 12 and the third foil 14 are reduced through a half-etching process (S4). The reduction in the thicknesses facilitates formation of the via hole 140 to be described later, and also facilitates removal of the second foil 12 and formation of the second circuit pattern 120.

To do so, the carrier 13 is removed, and the half-etching process is performed on the second foil 12 and the third foil 14.

In the embodiment, in the half-etching process, the thicknesses of the second foil 12 and the third foil 14, which are from about 12 μm to about 18 μm, may be reduced to about 2 μm or less, and more particularly, to about 1 μm to about 2 μm. In the embodiment, as each of the second foil 12 and the third foil 14 includes a copper foil, half-etching may be performed by using an etchant to etch the copper foil. A sulfuric acid hydrogen peroxide-based etchant may be used as an example of an etchant for etching a copper foil.

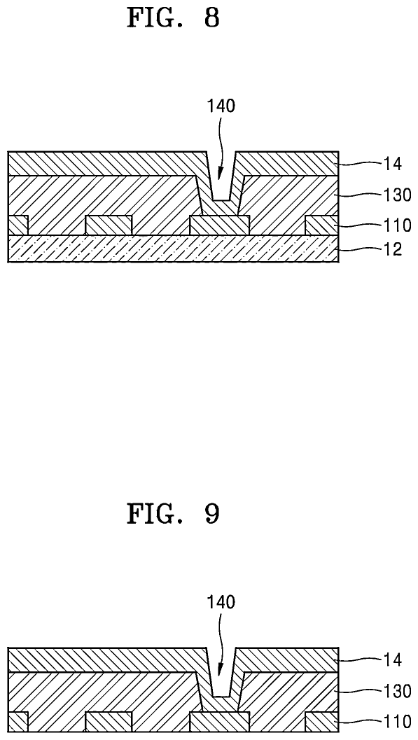

Next, as illustrated in FIG. 8, the via hole 140 electrically connecting the first circuit pattern 110 to the third foil 14 is formed (S5).

A well-known technology may be used to form the via hole 140. For example, after forming a hole through laser drilling, a general mechanical drilling method, and a chemical etching method, the via hole 140 electrically connecting the first circuit pattern 110 to the third foil 14 may be formed by using electroless plating, electroplating, and the like.

According to the embodiment, the process of manufacturing the circuit board 100 includes the forming of the via hole 140, but the disclosure is not limited thereto. That is, according to design, the process of manufacturing the circuit board 100 may not include the forming of the via hole 140.

Next, as illustrated in FIG. 9, the second foil 12 having a reduced thickness may be removed (S6).

Various methods known in public, e.g., a physical peeling method to separate the second foil 12 from the first circuit pattern 110 and the insulating layer 130 by applying a force to the second foil 12, a method of removing the second foil 12 by chemical etching, and the like, may be applied to remove the second foil 12.

As described above, the second foil 12 may be easily removed through the physical peeling method in a case where the peeling strength between the first foil 11 and the second foil 12 is 0.2 kgf/cm² or less, a case in which the peeling layer is disposed between the first foil 11 and the second foil 12, and the like. A sulfuric acid hydrogen peroxide-based etching material may be used as an etching material when the second foil 12 is removed through a chemical etching method.

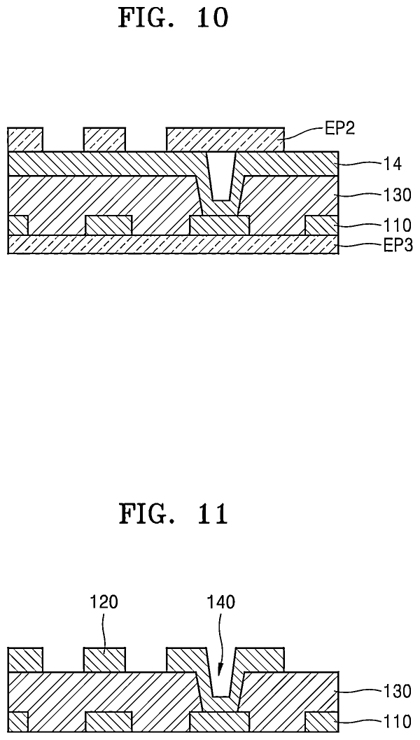

Next, as illustrated in FIGS. 10 and 11, the second circuit pattern 120 may be formed by etching the third foil 14 (S7).

More particularly, a DFR is disposed on a top surface of the third foil 14, a second etching resist pattern EP2 is formed by using a photolithography process such as mask exposure and development, and an etching resist layer EP3 is formed by disposing a DFR on a surface, from which the second foil 12 has been removed, to protect the first circuit pattern 110 during etching. Next, the second circuit pattern 120 is formed by etching the third foil 14 by using the second etching resist pattern EP2 that has been formed (see FIG. 11).

A sulfuric acid hydrogen peroxide-based etchant may be used as an example of an etchant used in a process of etching the third foil 14.

Next, after removing the second etching resist pattern EP2 and the etching resist layer EP3, a solder resist layer 150 covering a portion of the first circuit pattern 110 and the second circuit pattern 120 is arranged, and thus the circuit board 100 illustrated in FIG. 1 is formed (S8).

A method of arranging the solder resist layer 150 may be performed by using a solder resist material known in public, according to an arrangement method known in public, and therefore, details thereof will not be described.

In the method of manufacturing the circuit board 100 according to the disclosure, the manufacturing is performed through a roll-to-roll process. That is, the circuit board 100 may be manufactured by sequentially performing the aforementioned manufacturing processes while drawing out the first foil 11, the second foil 12, and the third foil 14 and the like by using at least one reel type un-coiler. By manufacturing through the roll-to-roll process, man-hour and manufacturing time may be reduced, and therefore, the productivity may be improved. The circuit board 100 manufactured may be wound to a re-coiler to be kept.

In the method of manufacturing the circuit board 100, according to the embodiment, the manufacturing is performed through the roll-to-roll process, but the disclosure is not limited thereto. That is, according to the disclosure, the circuit board may be manufactured in panel units through transferring and processing a material having a panel shape, not through the roll-to-roll process.

As described above, through the method of manufacturing the circuit board 100, according to the embodiment, a microcircuit pattern may be formed even when a plating process is not formed to form the circuit pattern, unlike the MSAP method in the related art, and therefore, cost and time for manufacturing may be reduced, and the yield and mass productivity of the product may be improved.

In the method of manufacturing the circuit board according to an aspect of the disclosure, as a plating method is not used to form the circuit pattern, processing cost and manufacturing time may be reduced, and the efficiency and yield in manufacturing may be improved.

Although the disclosure has been described with reference to the embodiments illustrated in the accompanying drawings, the embodiments are only examples, and those skilled in the art shall understand that various modifications and other equivalent embodiments may be made therefrom. Accordingly, the scope of the disclosure will be defined by the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of manufacturing a circuit board, the method comprising:
preparing a first stack in which a first foil and a second foil are stacked, wherein a thickness of the second foil is greater than a thickness of the first foil;
forming a first circuit pattern by etching the first foil;
forming a second stack by arranging an insulating layer and a third foil, the insulating layer covering the first circuit pattern and the third foil attached to the insulating layer;
reducing the thickness of the second foil and a thickness of the third foil through a half-etching process;
removing the second foil of which the thickness has been reduced; and
forming a second circuit pattern by etching the third foil.

2. The method of claim 1, wherein the thickness of the first foil of the first stack is from about 2 μm to about 3 μm.

3. The method of claim 1, wherein the thickness of the second foil of the first stack is from about 12 μm to about 18 μm.

4. The method of claim 1, wherein the first stack comprises a carrier attached to the second foil.

5. The method of claim 1, wherein the thickness of the third foil of the second stack is from about 12 μm to about 18 μm.

6. The method of claim 1, further comprising,
before the removing of the second foil of which the thickness has been reduced, forming a via hole electrically connecting the first circuit pattern to the third foil.

7. The method of claim 1, wherein,
after the removing of the second foil of which the thickness has been reduced, when an etching resist pattern is formed in the third foil to form the second circuit pattern by etching, an etching resist layer is formed on a surface, from which the second foil has been removed, to protect the first circuit pattern during etching.

8. The method of claim 1, further comprising,
after the forming of the second circuit pattern, arranging a solder resist layer covering a portion of the first circuit pattern and a portion of the second circuit pattern.
